(19) United States
(12) Patent Application Publication
(10) Pub. No.: US 2010/0301884 A1
(43) Pub. Date: Dec. 2, 2010

(54) THIN-FILM PROBE SHEET AND METHOD OF MANUFACTURING THE SAME, PROBE CARD, AND SEMICONDUCTOR CHIP INSPECTION APPARATUS

(76) Inventors: Etsuko Takane, Yokohama (JP); Yasunori Narizuka, Hiratsuka (JP); Akira Yabushita, Yokohama (JP); Kenji Kawakami, Kai (JP); Akio Hasebe, Kodaira (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/787,869

(22) Filed: May 26, 2010

(30) Foreign Application Priority Data
May 29, 2009 (JP) 2009-131298

(51) Int. Cl. G01R 31/02; H01R 13/02; H01R 43/00

(52) U.S. Cl. 324/754; 439/884; 29/885

(57) ABSTRACT

A semiconductor chip inspection apparatus largely reduces occurrence of damage due to foreign matter in an inspection process and improves durability at the same time of miniaturization is provided. As to a highly accurate thin-film probe sheet which performs: a contact to electrode pads arranged at a narrow pitch and a high density along with integration of semiconductor chip; and an inspection of semiconductor chips, by providing two layers of metal films selectively removable in a step-like shape in a periphery region of fine contact terminal having sharp tips and arranged at a high density and a narrow pitch at the same level as electrode pads, an upper periphery of the contact terminals is covered with an insulating film, and a large space region is formed.

### CROSS-REFERENCE TO RELATED APPLICATION

The present application claims priority from Japanese Patent Application No. 2009-131298 filed on May 29, 2009, the content of which is hereby incorporated by reference into this application.

### BACKGROUND OF THE INVENTION

The present invention relates to a thin-film probe sheet, a thin-film probe card, a connection device, a semiconductor chip inspection apparatus, a semiconductor chip manufacturing apparatus, or a semiconductor chip manufactured by using the semiconductor chip manufacturing apparatus. More particularly, the present invention is suitably applied to a connection to a semiconductor chip in which narrow-pitch microelectrode pads are arrayed at a high density, or a simultaneous connection to a large number of electrode pads.

Semiconductor modules in recent years have been very actively shifted to multi-chip modules on which semiconductor chips, for example, LSIs or memories etc. are integrated. It largely relies upon significant improvements in integration of semiconductor chips by introducing bare chips.

FIG. 1A is a perspective view illustrating a silicon wafer 1 on which a large number of semiconductor chips 2 are arranged in parallel, and FIG. 1B is a perspective view illustrating one of the semiconductor chips 2 in an enlarged manner. The large number of semiconductor chips 2 are formed on the silicon wafer 1 and arranged in parallel, and they are later cut into pieces for use. On a surface of the semiconductor chip 2, a large number of electrode pads 3 are aligned along the circumference of the semiconductor chip 2. The higher the degree of integration of the semiconductor chips 2 is, the narrower the pitch of the electrode pads 3 is and the higher the density of the electrode pads 3 is. Pitch of electrode pads has been advanced to be 200 μm or smaller, for example, 130 μm, 100 μm, or even smaller, and products of near 40 μm are under development. To increase the density of electrode pads, the trend is to arrange electrode pads in one line to two lines along the circumference of the pad, and moreover, to the whole surface of the pad. Also, speed increase of semiconductor chips has been significant, and clock of microcomputers has reached several gigahertz order. To manufacture such semiconductor chips and multi-chip modules to embed the semiconductor chips with a good yield, technology of efficiently inspecting electrical characteristics is desired in the final step of the manufacture process of the semiconductor chips. To respond to this, there has been a connection device under development having a mechanism in which fine contact terminals are connected to a high density to an inspection wiring board on which wirings are formed with a high density.

Conventionally, in the case of semiconductor chips having a sufficiently large pad pitch, inspecting means using a probe card of cantilever system, on which tungsten needles obliquely protruding from a wiring board for inspection are orderly arranged, has been generally used as an easy and simple inspection probe.

However, regarding the advance of narrow pitch as mentioned above, such a system has a limitation in thinning of the needles. In addition, while the needles are rubbed onto the pad and abraded away to achieve low-resistance contacts made by breaking oxide films on electrode surfaces, abrasion endurance is significantly degraded due to thinning of the needles, and thus it has been a bottleneck of an increase in manufacture cost as a whole as maintenance is frequently needed to maintain positional accuracy at the needle tips. Thus, the cantilever system using tungsten needles is becoming difficult to be compatible to miniaturization.

As means for solving these problems, means of achieving formation of contact terminals maintaining endurance and high accuracy as well as miniaturization is suggested in Japanese Patent Application Laid-Open Publication No. H07-283280 (Patent Document 1), Japanese Patent Application Laid-Open Publication No. 2005-24377 (Patent Document 2), and Japanese Patent Application Laid-Open Publication No. 2006-118945 (Patent Document 3).

However, the inspection technology of semiconductor Chips by a probe card as suggested in Patent Document 1 has the following problems.

By a size-reduction of semiconductor chips and a diameter enlargement of semiconductor wafers, the number of semiconductor chips is increased, and time taken for inspecting these chips is thus exponentially increased. To manufacture a semiconductor chip inspection apparatus compatible to microelectrode pads arranged at a narrow pitch, formation of contact terminals being fine and arranged at a narrow pitch corresponding to the electrode pads, and an improvement in the degree of perfection of a thin-film probe sheet having wirings at a narrow pitch are required. In addition, in the inspection, while inspection time may be shortened at the same time if a pattern which enables the inspection on not only one semiconductor chip but also a plurality of semiconductor chips simultaneously in a batch is formed, in both the cases, it is important to form the shape and the position of contact terminals at a high accuracy.

According to Patent Document 1, holes to be molds for forming contact terminals are formed by anisotropic etching on (100) plane of a silicon wafer and filling a metal into the molds to form the contact terminals. An insulating film formed of a polyimide film and a lead wiring are formed in another step. Further, between the insulating film and a wiring board, a buffer layer and a silicon wafer to be a substrate are sandwiched to be together as one, and then the molds are removed. Thereafter, the lead wirings are connected to electrode pads of the wiring board.

A shape of the contact terminal is a four-sided pyramid reflecting the hole formed to the silicon wafer. A size of the hole depends on a size of an opening provided to silicon dioxide by photolithography and etching conditions. A pitch of the holes is determined by a pitch of the openings.

Thus, regarding the shape of the contact terminal, for example, a concave mold of a four-sided pyramid, which has a depth of 15 μm when a base of the pyramid is 20 μm, is formed, and an allowable pitch of the arrangement of the contact terminals can be compatible to miniaturization by selecting any size of the base.

Also, because of the processing by photolithography and anisotropic etching, the shape and size of the contact terminal can be formed with a good precision, and the oxide film can be broken at a ridge line of the protrusion only by a pressuring action upon measurement instead of the scribing action mentioned above. Thus, scratches to the electrode pad can be small and an inspection with a stable contact resistance value can be achieved.

However, to achieve such a miniaturization that the pitch of electrode pads of the semiconductor chip is 100 μm or smaller, a height of the contact terminal has an effective limited size up to about 30 μm. Thus, to achieve a narrower pitch, the height is necessarily made smaller.

A problem in the inspection process using a thin probe sheet is a property of an electrode surface of a semiconductor device etc. to be subjected to the measurement. More specifically, protrusions due to abnormal segregation of a plating metal film or foreign matter to be extrinsically taken in disturb a stable contact; or a large protrusion may pose a critical failure such as crush or deformation of the thin film sheet and/or contact terminals. Therefore, it is preferable to form the contact terminals as high as possible although it conflicts the pitch reduction.

Patent Documents 2 and 3 describe contents in consideration of these problems mentioned above, and they are techniques similar to the method of forming contact terminals by means of transferring from a mold using anisotropic etching of silicon. Meanwhile, according to Patent Document 2, one layer of a metal film that is selectively removable is disposed in vicinity and surrounding regions of a plurality of contact terminals, and the metal film is removed in a back-end process to provide spacing between contact terminals. In Patent Document 3, one layer of a metal film disposed on a plurality of contact terminals and in a vicinity and surrounding region of the contact terminals is selectively removed except for the regions where the contact terminals are formed, and the metal film is covered with a resin base material formed of an insulating layer, and moreover, spacing is provided between the contact terminals.

According to the above means, forming the contact terminals high is effective for solving occurrence of damages from foreign matter and so forth.

### SUMMARY OF THE INVENTION

Meanwhile, as a pitch reduction advances and further miniaturization is required, more than a little foreign matters having a size exceeding a height of the contact terminals about 30 μm obtained according to Patent Documents 2 and 3 exist in a prober that is an operation environment of the thin-film probe, and a fear of destroying the thin-film probe sheet and an inspected object is not negligible.

Also, Japanese Patent Application Laid-Open Publication No. 2008-164486 (Patent Document 4) discloses technique for ensuring a height of a probe by selectively depositing a copper film in a region outside an adhesion ring for preventing breakage of a thin-film probe sheet and an inspected object, then forming an insulating layer and a wiring layer, and then removing the copper film. However, also in this technique, the height may not be sufficient to foreign matters exceeding the height of contact terminals of about 30 μm.

A preferred aim of the present invention is to provide an inspection technology of a semiconductor chip compatible to simultaneous connections to a large number of electrode pads and/or electrode pads of a plurality of chips using a probe card formed with a thin-film probe sheet, on which contact terminals are arranged at a narrow pitch at the same level as a pitch of electrode pads and with a high density and high positional accuracy, having a contact terminal height larger than that of conventional ones.

The above and other preferred aims and novel characteristics of the present invention will be apparent from the description of the present specification and the accompanying drawings.

The typical ones of the inventions disclosed in the present application will be briefly described as follows.

(1) A thin-film probe sheet including: a plurality of contact terminals electrically contacting with electrodes disposed to an inspected object; individual wiring led out from the contact terminal via a through hole in an insulating layer; and a plurality of peripheral electrodes electrically connected to the wirings and also connected to electrodes of a wiring board, wherein a shape of the plurality of contact terminals is a four-sided pyramid or a trapezoidal four-sided pyramid, a second metal film and a third metal film being selectively removable are disposed in a peripheral region of a first metal film forming the contact terminals, spacing is provided between the contact terminals by removing the second metal film and the third metal film in a back-end process, and a height of the contact terminal is large.

(2) A thin-film probe sheet including: a plurality of contact terminals electrically contacting with electrodes disposed to an inspected object; individual wiring led out from the contact terminal via a through-hole in an insulating layer; and a plurality of peripheral electrodes electrically connected to the wirings connected to electrodes on a wiring board, wherein a base-material sheet forming the thin-film probe sheet has a region for forming the plurality of contact terminals positioned lower than peripheral regions of the plurality of contact terminals.

(3) A thin-film probe sheet including: a plurality of contact terminals electrically contacting with electrodes disposed to an inspected object; individual wiring led out from the contact terminal via a through-hole in an insulating layer; and a plurality of peripheral electrodes electrically connected to the wirings connected to electrodes on a wiring board, wherein a second metal film and a third metal film being selectively removable are disposed in a peripheral region of a first metal film forming the contact terminal, and the third metal film is formed to be shifted toward the outside of the contact terminal and in a step-like shape on the second terminal, so that a periphery of the contact terminals is covered with a resin base material forming an insulating film.

(4) The probe sheet wherein the contact terminals are formed of at least one metal selected from a group of nickel, rhodium, palladium, iridium, ruthenium, tungsten, chrome, copper, and tin; or a stacked alloy films of the metals mentioned above.

(5) The second metal film and the third metal film are formed of at least one metal selected from nickel, copper, and tin.

(6) A method of manufacturing a thin-film probe sheet including: a plurality of contact terminals electrically contacting with electrodes disposed to an inspected object; individual wiring led out from the contact terminal via a through-hole in an insulating layer; and a plurality of peripheral electrodes electrically connected to the wirings connected to electrodes on a wiring board, the method including the steps of: forming a second metal film to peripheral regions of hole portions to which the plurality of contact terminals are formed and then forming a first metal film forming the plurality of contact terminals to the hole portions; forming a resist covering the first metal film; forming a third metal film on the second metal film and then removing the resist; forming the wiring connected to the first metal film and then forming a protective film for protecting the wiring; and removing the second metal film and the third metal film.

(7) The method of manufacturing a thin-film probe sheet wherein, in the step of forming the first metal film after forming the second metal film, a film resist is formed like a window roof above the hole portions by photolithography, and then the first metal film is formed to the hole portions.

(8) The method of manufacturing a thin-film probe sheet wherein, in the step of forming the first metal film, a column portion and the contact terminal portion formed of the first metal film are formed by a photolithography step and a plating step.

(9) A probe card including a thin-film probe sheet, wherein a wiring board on which the thin-film probe sheet is mounted; and a pressuring means which applies pressuring force are provided.

(10) A semiconductor chip inspection apparatus including the thin-film probe sheet described above.

Moreover, other typical ones of the inventions disclosed in the present application will be briefly described as follows.

(11) A probe sheet such as that described above, wherein a metal pillar shape of the plurality of contact terminals formed of the first metal film is formed of a supporting pillar shape of a polygonal column or a cylinder shape; a depth or a height of a concave of a space region, in which the first metal film forming the contact terminal and the second and third metal film being selectively removed are formed, is 30 to 40 μm that is a sufficiently larger size than a height of 15 μm of the trapezoidal four-sided pyramid shape of the tip of the contact terminal, so that the height of the contact terminal is large.

(12) A semiconductor chip inspection apparatus mounting a probe card having a structure of a thin-film probe sheet such as that described above, wherein any thicknesses of the first metal film which forms the contact terminal and the second and third metal films which will be selectively removed in a back-end process are selected, and a large space region is provided to a polyimide sheet which is a base material sheet, thereby reducing occurrence of damages due to foreign matters taken in extrinsically in an inspection step as small as possible.

(13) A thin-film probe sheet such as that described above capable of maintaining a height of the contact terminal being larger than that of conventional ones even by the same technique of forming hole molds having a shallow depth by anisotropic etching of silicon in a conventional manner, also with respect to miniaturized types having an electrode pad pitch smaller than 50 μm, thereby achieving an inspection at a narrow pitch and long-life.

The effects obtained by typical aspects of the present invention will be briefly described below.

(1) Occurrence of damages can be reduced as much as possible with respect to various foreign matters generated in a manufacturing process of an inspected object such as a semiconductor chip.

(2) According to the above-mentioned effect of item (1), yield can be improved in a bonding step in manufacture of a semiconductor device after an inspection of the semiconductor chip and so forth.

(3) Also, a low-resistance and stable connection can be achieved without damages on the thin-film probe sheet and the inspected object due to generation of indentation and/or debris.

(4) Further, it is possible to perform an inspection ensuring a high tip-position accuracy of the contact terminals, thereby surely enabling inspections of semiconductor devices having narrow-pitch electrode structures.

(5) Since the contact terminals formed of the first metal film and column portions can be formed by one photolithography step and a plating step, a positional shift failure posed by repeating photolithography and a cost can be reduced.

(6) By forming a film resist to be like a window roof above a contact terminal hole after forming a second metal film in a vicinity and surrounding region of contact terminals, according to a result of an experimental study by the inventors of the present invention, it has been confirmed that occurrence of voids in the plating of the first metal film is suppressed, and, by forming the third metal film and the second metal film step-like, a thin-film probe sheet having more insulating layers in a vicinity and at an upper portion of the contact terminals can be manufactured.

(7) Moreover, a more long-life inspection apparatus mounting a thin-film probe sheet thereon is achieved, and, at the same time, a manufacturing cost of semiconductor devices can be largely reduced.

### BRIEF DESCRIPTION OF THE DRAWINGS

FIG. 1A is a perspective view illustrating a wafer that is an inspected object on which semiconductor chips are arranged;

FIG. 1B is a perspective view illustrating a semiconductor chip;

FIG. 2 is a cross-sectional configuration diagram of a whole of a thin-film probe sheet according to a first embodiment of the present invention;

FIG. 3A is a schematic cross-sectional view illustrating a manufacturing step of the thin-film probe sheet of FIG. 2;

FIG. 3B is a schematic cross-sectional view illustrating a manufacturing step of the thin-film probe sheet of FIG. 2;

FIG. 3C is a schematic cross-sectional view illustrating a manufacturing step of the thin-film probe sheet of FIG. 2;

FIG. 3D is a schematic cross-sectional view illustrating a manufacturing step of the thin-film probe sheet of FIG. 2;

FIG. 3E is a schematic cross-sectional view illustrating a manufacturing step of the thin-film probe sheet of FIG. 2;

FIG. 3F is a schematic cross-sectional view illustrating a manufacturing step of the thin-film probe sheet of FIG. 2;

FIG. 3G is a schematic cross-sectional view illustrating a manufacturing step of the thin-film probe sheet of FIG. 2;

FIG. 3H is a schematic cross-sectional view illustrating a manufacturing step of the thin-film probe sheet of FIG. 2;

FIG. 3I is a schematic cross-sectional view illustrating a manufacturing step of the thin-film probe sheet of FIG. 2;

FIG. 3J is a schematic cross-sectional view illustrating a manufacturing step of the thin-film probe sheet of FIG. 2;

FIG. 3K is a schematic cross-sectional view illustrating a manufacturing step of the thin-film probe sheet of FIG. 2;

FIG. 4 is an explanatory diagram illustrating a relation of a cross-sectional configuration and a shape outline for describing the manufacturing process of the thin-film probe sheet of FIG. 2;

FIG. 5 is a schematic diagram illustrating an outline of characteristics of plating segregation to a contact-terminal hole mold according to the first embodiment of the present invention;

FIG. 6A is a schematic diagram illustrating a difference in segregation characteristics upon filling plating into deep holes caused by a difference in methods of forming a film resist according to a second embodiment of the present invention;

FIG. 6B is a schematic diagram illustrating a difference in segregation characteristics upon filling plating into deep holes caused by a difference in methods of forming a film resist according to the second embodiment of the present invention;

FIG. 7A is a schematic diagram illustrating metal films and a summary of a thickness relation of the metal films according to a third embodiment of the present invention;

FIG. 7B is a schematic diagram illustrating metal films and a summary of a thickness relation of the metal films according to the third embodiment of the present invention;

FIG. 7C is a schematic diagram illustrating metal films and a summary of a thickness relation of the metal films according to the third embodiment of the present invention;

FIG. 8A is a structural diagram illustrating an arrangement of a thin-film probe sheet according to a fourth embodiment of the present invention;

FIG. 8B is a structural diagram illustrating an electrode pad of a semiconductor device compatible to a liquid crystal display panel according to the fourth embodiment of the present invention;

FIG. 8C is a structural diagram illustrating the electrode pad of a semiconductor device compatible to a liquid crystal display panel according to the fourth embodiment of the present invention;

FIG. 8D is a structural diagram illustrating the electrode pad of a semiconductor device compatible to a liquid crystal display panel according to the fourth embodiment of the present invention;

FIG. 9A is a plan view illustrating a relation of an arrangement summary of the electrode pads and contact terminals according to the fourth embodiment;

FIG. 9B is a schematic cross-sectional view illustrating a state of plating segregation of the electrode pad of the semiconductor device to which a gold bump is formed according to the fourth embodiment;

FIG. 10 is a schematic diagram of a planar appearance of a thin-film probe sheet according to a fifth embodiment for describing problems of the thin-film probe sheet;

FIG. 11A is a schematic diagram of a planar appearance of the thin-film probe sheet of FIG. 10 in which a dummy wiring is formed in a vicinity of contact terminals;

FIG. 11B is a schematic diagram of a wiring configuration of the thin-film probe sheet of FIG. 10 in which a dummy wiring is formed in a vicinity of contact terminals;

FIG. 11C is a schematic diagram of a wiring configuration of the thin-film probe sheet of FIG. 10 in which a dummy wiring is formed in a vicinity of contact terminals;

FIG. 12 is a schematic diagram illustrating a thin-film probe sheet of FIG. 10 on which a dummy wiring and a supporting metal are formed in a contact terminal region;

FIG. 13 is a cross-sectional view illustrating an outline of an aspect of an inspection probe card on which a thin-film probe sheet according to a seventh embodiment is formed;

FIG. 14 is a diagram illustrating a whole configuration of a semiconductor chip inspection apparatus using the inspection probe card of FIG. 13;

FIG. 15 is a schematic diagram illustrating an appearance of an inspection to a semiconductor chip, on which electrode pads are aligned, by the semiconductor chip inspection apparatus of FIG. 14;

FIG. 16 is a process diagram illustrating an example of an inspection process of a semiconductor device according to the seventh embodiment of the present invention; and

FIG. 17 is a basic configuration diagram of a probe card for an inspection to be performed at the wafer level as a quality test such as electric characteristics of the semiconductor chip of FIG. 1.

### DETAILED DESCRIPTION OF PREFERRED EMBODIMENTS

Hereinafter, an embodiment of the present invention will be described with reference to the accompanying drawings. Note that the same reference numeral/symbol denotes the same part, repetitive descriptions may be omitted, and dimensional ratio of each part is changed from actual one to facilitate understanding of descriptions.

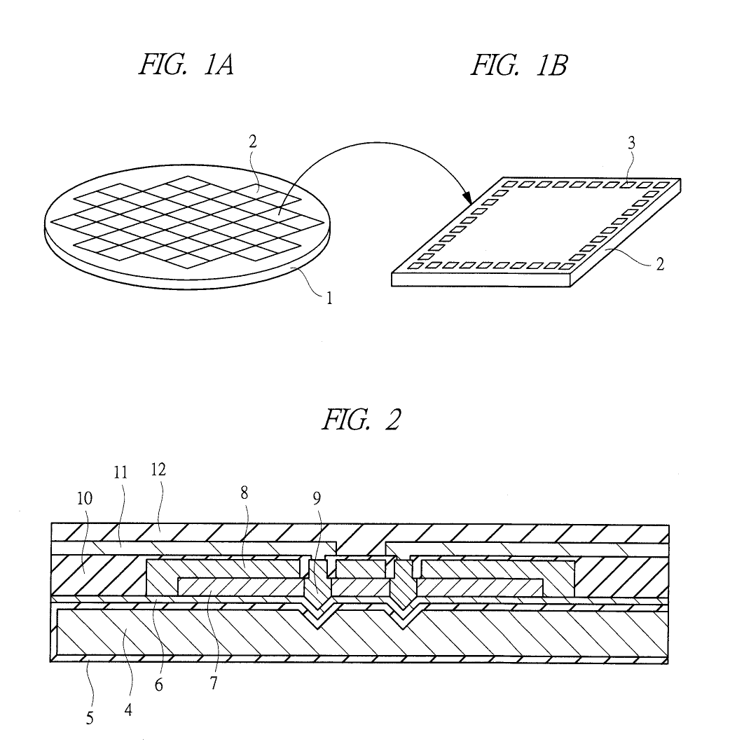

In the present specification, main terms are defined as follows. A semiconductor device can be any of one in a wafer state on which circuits are formed (e.g., FIG. 1A), a semiconductor element (e.g., FIG. 1B), or one after being packaged (QFP, BGA, CSP, etc.). Note that FIG. 1A illustrates one example of an inspected object, and an arrangement of electrodes can be any of a peripheral electrode arrangement or a whole-surface electrode arrangement. A probe sheet is a structure body which functions as a connector, which is connected to an inspected object, for electrically connecting a tester that is a measuring instrument and the inspected object.

### Summary of Embodiments

An embodiment of the present invention provides a semiconductor chip inspection apparatus as a high-accuracy thin-film probe sheet performing contacts with electrode pads arranged at a narrow pitch and a high density along with high integration of semiconductor chips, and an inspection of a semiconductor chip, the thin-film probe sheet having: a first metal film forming contact terminals each being in a shape of a four-sided pyramid or a trapezoidal four-sided pyramid having a sharp tip; and selectively removable two layers of metal films (second metal film and third metal film) arranged in a peripheral region of the thin-film probe sheet for fine contact terminals arranged at a high density and a narrow pitch at the same level as the electrode pads, wherein the third electrode is arranged in a step-like shape to cover an upper-periphery of the contact terminal, and a large space region is formed, thereby largely reducing occurrence of damages due to foreign matter in an inspection step and improving endurance at the same time with miniaturization.

The thin-film probe sheet of the embodiment of the present invention has a feature that two layers of selectively removable metal films of the second metal film and the third metal film are formed so that a height of the contact terminals is further higher than the technique of using one layer of Patent Document 4 mentioned above.

In addition, in the thin-film probe sheet of the embodiment of the present invention, the contact terminals are formed of at least one metal selected from a group of nickel, rhodium, palladium, iridium, ruthenium, tungsten, chrome, copper, and tin, or a stacked film of alloy films of the aforementioned metals. Moreover, the second metal film and the third metal film are formed of at least one metal selected from nickel, copper, or tin.

Hereinafter, examples based on the summary of embodiments described above will be specifically described in the embodiments.

### First Embodiment

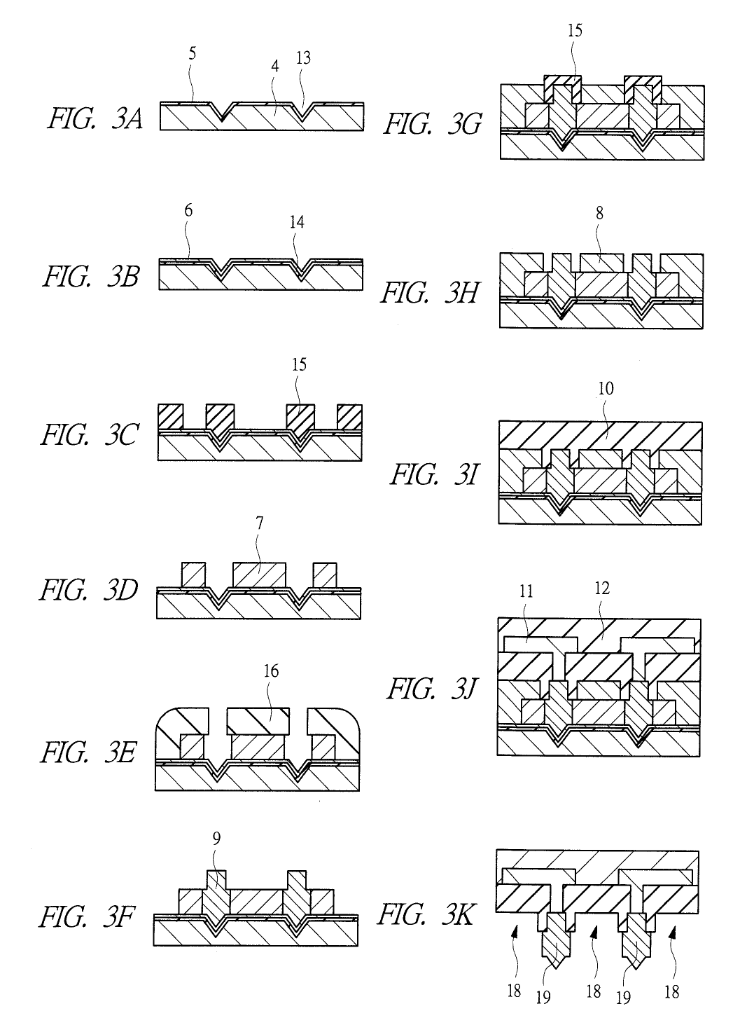

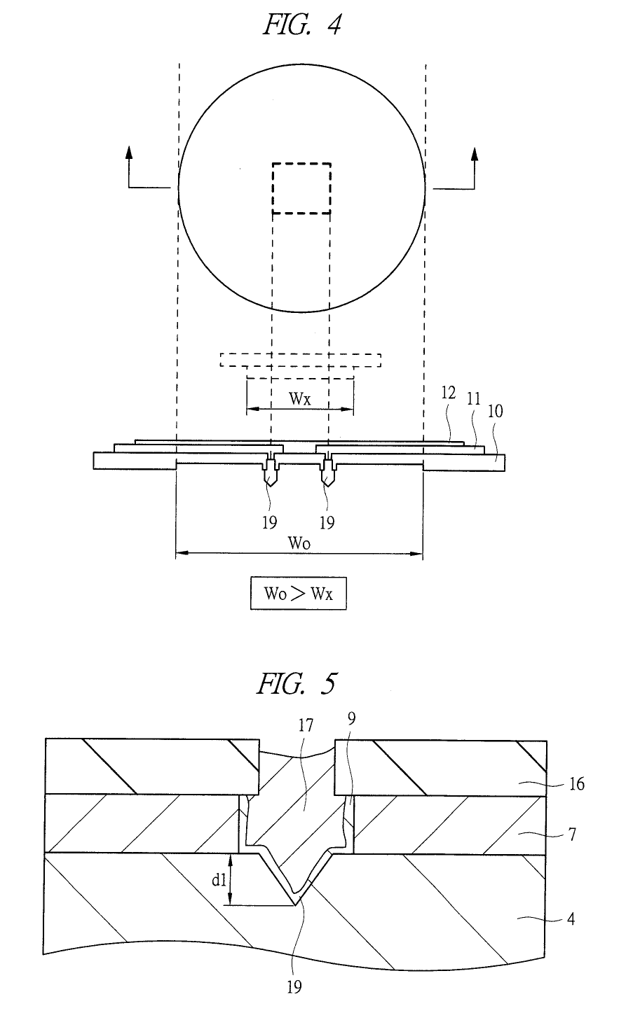

FIG. 2 is a cross-sectional configuration diagram of a whole of a thin-film probe sheet according to a first embodiment of the present invention, FIGS. 3A-3K are schematic cross-sectional views illustrating a manufacturing process of the thin-film probe sheet of FIG. 2, and FIG. 4 is an explanatory diagram illustrating a relation of a cross-sectional configuration and a shape outline for describing the manufacturing process of the thin-film probe sheet of FIG. 2.

In the first embodiment, FIG. 2 and FIG. 3 illustrate a manufacture process of the thin-film probe sheet. FIG. 2 illustrates a structure of the thin-film probe sheet finished by a process of film-thinning on a silicon substrate which is a base material. FIGS. 3A-3K illustrate a flowchart of the manufacture process in detail.

First, to a (100) plane of a silicon substrate 4 which is a single crystal silicon wafer, a pattern region for forming contact terminals is formed by photolithography on a surface of the substrate on which a silicon oxide film 5 having a thickness of 0.2 μm, and the silicon substrate 4 is dipped in a mixed solution of hydrofluoric acid and ammonium fluoride to etch the silicon oxide film 5 at opening portions.

Second, a resist film is removed and hole molds 13 in four-sided pyramid shape are processed by anisotropic etching by heated potassium hydroxide solution at a high temperature of 90° C. (FIG. 3A).

In this manner, the hole molds 13 for contact terminals by a plurality of openings having a side length of the base of 20 μm and a vertical depth of 15 μm arranged at a 50-μm interval are formed. Again, a thermal oxidation processing is performed to form the silicon oxide film 5 over the whole of the base material.

Next, a stacked film of chrome (0.1 μm) and copper (0.5 μm) is formed by sputtering as a plating base metal film 6 (FIG. 3B).

The present invention has such a feature that a contact terminal tip portion and a pillar portion formed of a first metal film are formed by one photolithography step and a plating step, thereby reducing cost and positional shift defects caused by repeating photolithography.

Next, a resist pattern for forming a second metal film 7 is formed (FIG. 3C). When considering reduction of defect occurrence due to a residual resist at a bottom portion of the contact terminal hole in the back-end process, the resist pattern is preferable to be formed by a liquid resist 15.

A pattern formation area of the liquid resist 15 has a diameter of Ø60 nm and is formed in a circular shape larger than a diagonal length of the four-sided pyramid shape for contact terminals formed in the front-end process by several μm to protect the contact terminal hole molds 13 having a diameter of Ø32 μm. A thickness of the resist film is about 25 μm.

Next, a second metal film 7 is formed (FIG. 3D). Plating of the second metal film 7 is copper and a thickness of the same is about 20 μm.

In addition, after removing the resist pattern 15, with a film resist 16 having a thickness of 45 μm, photolithography for forming the first metal film is performed (FIG. 3E).

Next, a first metal film 9 to form contact terminals is formed by electroplating by being filled in voids formed with the hole mold 13 in four-sided pyramid shape, the second metal film, and the film resist 16 (FIG. 3F).

The plating film is formed of 4 to 5 μm of a hard metal film (first metal film) 9 (FIG. 5) of rhodium, and a 60 to 70 μm of an auxiliary metal film (first metal film) 17 (FIG. 5) of nickel.

Next, after removing the film resist pattern 16, the resist pattern 15 is formed with a diameter of Ø40 μm onto an upper edge portion of the contact terminal to newly form a third metal film 8 (FIG. 3G). By the resist pattern formation, the third metal film 8 can be formed in a step-like shape with respect to the second metal film 7, and thus, as a result, a thin-film probe sheet having more insulating layers around the upper portion of the contact terminals can be formed.

Next, the third metal film 8 is formed (FIG. 3H). Plating of the third metal film 8 is copper and a thickness is about 20 μm.

In addition, after removing the resist pattern 15, polyimide resin to be a base-material sheet is formed by spin coating, and a thermal curing step is performed at 350° C. to form an insulating film 10 having a thickness of 18 μm (FIG. 3I).

Further, aluminum (thickness of 2 μm) is deposited on the polyimide film by sputtering, a resist pattern for processing through-holes is formed, and openings are formed to the insulating film 10 of polyimide by etching the aluminum film in a mixed acid composed mostly of phosphoric acid. Subsequently, through-holes are formed to the polyimide film by reactive ion etching using oxygen as a main reaction gas until a nickel film surface of the stacked auxiliary metal film 17 forming the contact terminals is exposed. Then, soaking in aqueous sodium hydroxide is performed to remove the aluminum film (not illustrated).

On the polyimide film including sidewalls of the through hole, chrome (0.1 μm) and copper (0.5 μm) as a plating base metal film for wiring formation are deposited by sputtering in the same manner as the previous step. Then, by a semi-additive method, resist patterning and copper plating are performed, and a pattern separation is performed to form wirings 11.

Each electroplating solution is a universal solution generally and commercially supplied, and processing conditions are normal.

In addition, as a protective film 12 of the wirings 11, a polyimide film (thickness is 6 μm) is formed in the same manner and a film-thinning step is performed on the silicon substrate (FIG. 3J).

Subsequently, to separate the silicon wafer and the polyimide base-material sheet on which each component is formed in the above-described process, first, a surface to be subjected to a film-thinning processing is protected, and thereafter, the silicon oxide film 5 on a back surface of the silicon substrate 4 is selectively removed by being soaked in a mixed solution of hydrofluoric acid and ammonium fluoride.

Next, the whole silicon wafer is subjected to etching by putting it in potassium hydroxide aqueous solution at 90° C. Thereafter, the silicon oxide film 5 on a front surface side of the silicon substrate 4 is removed in the same manner, and then chrome and copper formed as the plating base metal film 6 are removed by subsequently soaking in permanganic acid potassium salt solution and a salt-iron-based etching solution.

Further, copper formed as the contact terminal 19 and the selectively removable second metal film 7 and the third metal film 8 is removed in the same manner by soaking in a salt-iron-based etching solution, thereby forming a space region 18 composing the height of the contact terminals (FIG. 3K).

Details of a main structure of the thin-film probe sheet fabricated in the above-described process are illustrated in FIG. 4. FIG. 4 illustrates a plane of the whole of the thin-film probe sheet and an outline of a cross section of the same.

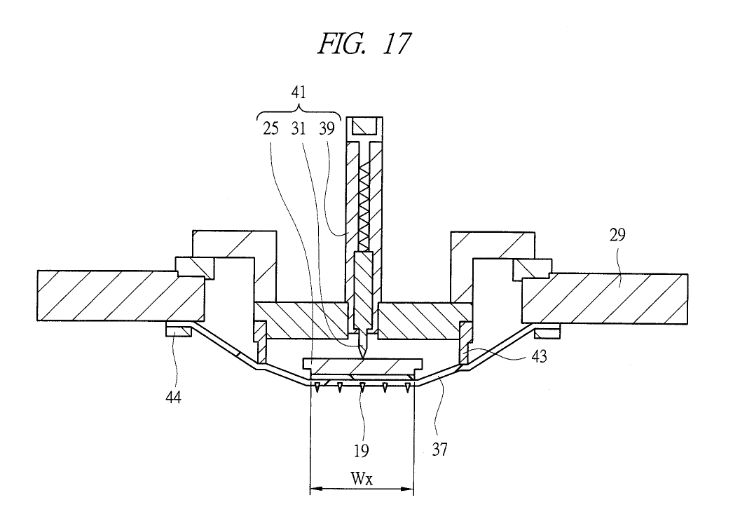

A formation region Wo (FIG. 4) for the second metal film 7 and the third metal film 8 to be selectively removed by etching and the contact terminals 19 has an outer diameter of Ø60 mm in the first embodiment. Meanwhile, there is no problem as long as Wo has a sufficiently larger size than a size Wx of a push piece 25 included in a pressing mechanism 41 of the probe card illustrated in FIG. 17 of a basic configuration diagram of an inspection probe card for performing quality inspection of electric characteristics etc. of semiconductor chips at wafer level, and Wo is a size suitably set according to product.

In addition, there is no problem in forming the third metal film 8 forming the space region 18 thicker. While a configuration in which a copper metal film is used has been described in the first embodiment, it is needless to say that other materials can obtain the same effects as long as the material can be selectively removed with respect to the metal film forming the contact terminals or the polyimide film of the base-material sheet.

Further, while the example of the structure described above has had a terminal pitch of 50 μm, a contact terminal diameter of 20 μm, space between terminals of 25 μm, there is no problem in achieving a minuter and narrower pitch as long as the conditions can achieve a resolution capability of the resist pattern processed in the photolithography.

Regarding the thin-film probe sheet as fabricated in the above-described manner, a thin-film probe sheet having a large space region of 55 μm that is a sum of a contact terminal height d1 of 15 μm formed by the hole mold 13 formed by anisotropic etching of silicon and a formation thickness of 40 μm of the copper plating film formed as the second metal film 7 and the third metal film 8 which are selectively removable.

Consequently, according to the first embodiment, it is possible to largely reduce causes of critical damages to fine contact terminals or neighboring probe sheets due to foreign matter externally taken in during a chip inspection, and a manufacture cost can be reduced at the same time as achieving a longer lifetime.

### Second Embodiment

According to a second embodiment, in a thin-film probe sheet basically having the same structure as that obtained in the manufacture process described in the first embodiment, a film resist is formed by photolithography in a shape like a window roof to an upper portion of the contact terminal hole after forming the second metal film in a vicinity of the contact terminal.

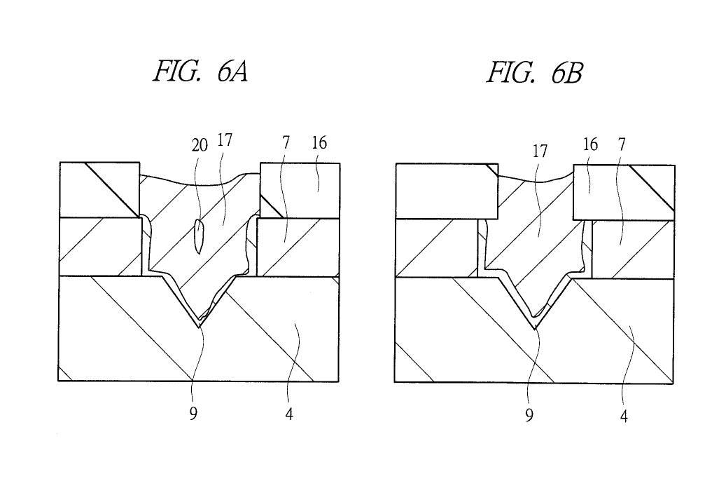

FIGS. 6A and 6B are schematic diagrams illustrating a difference in segregation upon a deep-hole plating filling according to a difference in film-resist formation method according to the second embodiment.

FIG. 6A illustrates an example of not forming the film resist 16 like a window roof, and FIG. 6B illustrates an example of forming the film resist 16 like a window roof. In both cases, the first metal film 9 and the auxiliary metal film 17 of the contact terminal plating are already filled. When the film resist 16 is formed like a window roof, since electric lines of force upon electroplating concentrate to an upper portion of the second metal film 7, the growth of plating is fast in the auxiliary metal film 17 at an upper portion of the contact terminal, plating formation ends earlier at the upper portion than the bottom of the contact terminal hole, causing a void 20 to occur in the auxiliary metal film 17. On the contrary, when the film resist 16 is formed like a window roof, concentration of electric likes of force at the upper portion of the contact terminal is adjusted, and thus occurrence of the void 20 in the auxiliary metal film 17 can be suppressed.

According to the foregoing, by suppressing occurrence of voids in the auxiliary metal film 17 of the first metal film 9 (according to an experimental study by the inventors) and forming the third metal film 8 in a step-like shape to the second metal film 7 in the manufacture method described in the first embodiment, a thin-film probe sheet having more insulating layers around an upper portion of the contact terminals can be fabricated.

According to the above structure, as well as achieving a reduction of stress on the pillar portion of the contact terminal upon performing an inspection contact on the wafer and chip, strength of the upper portion and periphery of the contact terminal can be increased.

### Third Embodiment

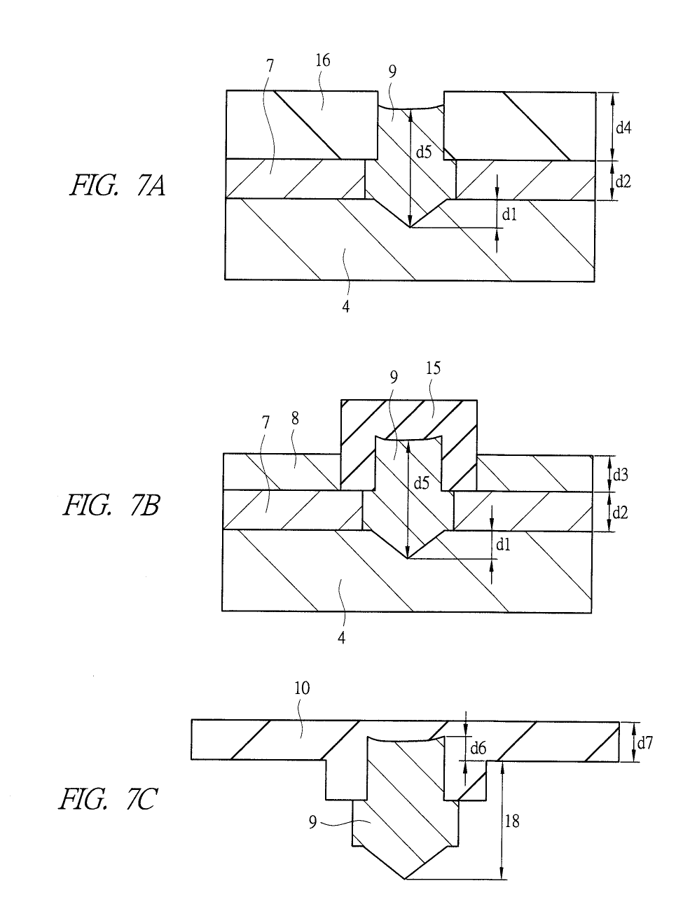

FIGS. 7A to 7C are schematic diagrams illustrating a summary of a relation between metal films and thicknesses of the metal films according to a third embodiment.

In the third embodiment, regarding a thin-film probe sheet basically having the same structure as that obtained in the manufacture process described in the first embodiment, an example of a thickness relation upon forming the second metal film and the third metal film for forming a height of the contact terminal of 45 to 55 μm after completing the thin-film probe sheet will be described with reference to FIGS. 7A to 7C.

With using anisotropic etching of the silicon substrate 4 that is a single crystal silicon wafer, a hole mold of the contact terminal is formed. In this manner, hole molds 13 for contact terminals by a plurality of openings having a side length of the base of 20 μm and a vertical depth of 15 μm arranged at a 50-μm interval are formed.

Next, copper is formed by electroplating for the second metal film 7 to be formed as means for increasing the height of the terminal in a periphery region of the contact terminal. The present invention has such a feature that a tip portion and a metal pillar of the fine contact terminal are formed in one photolithography step and a plating step of the first metal film 9.

To reduce defects in the back-end process due to the photolithography formation of the bottom portion of the contact terminal hole and a residual resist, the second metal film 7 is formed with using a liquid resist for fine pattern formation. In accordance with a resolution capability of the liquid resist, a thickness d2 of the second metal film 7 is set to be 5 μ≦d2≦20 μm. After forming copper of the second metal film 7 by electroplating, the resist covering the contact terminal holes is removed.

Next, as described in the second embodiment, the film resist 16 for forming the first metal film to form the contact terminals is formed by photolithography so that the film resist 16 has a shape like a window roof to an upper portion of the contact terminal hole (FIG. 7A).

To form a structure in which the upper portion of the contact terminal is more surely held inside the thin-film probe sheet, a thickness d5 of the first metal film 9 is set to be d1+d2+d3<d5 (FIG. 7B).

A thickness d7 of the insulating film 10 in the back-end process is 18 μm (FIG. 7C). Thus, a height d6 of the thickness d5 of the first metal film 9 protruding from the third metal film 8 is necessary to be smaller than 18 μm.

According to the foregoing, to form the thin-film probe sheet of the third embodiment, the thickness d5 of the first metal film 9 is necessary to be 45 μm<d5<63 μm. For example, to form a contact terminal height (space region) 18 of the finished thin-film probe sheet in the third embodiment to be 45 μm, when the thickness d4 of the second metal film 7 is 5 μm that is a minimum thickness condition, an additional height of 25 μm is necessary. In addition, as described above, to make the structure in which the upper portion of the contact terminal is more surely held inside the thin-film probe sheet, the contact terminal is desired to be formed by the first metal film 9 having d6 being smaller than 18 μm.

According to the foregoing, about 45 μm is sufficient for the thickness d4 of the film resist 16 for forming the first metal film to form the contact terminal.

After forming the film resist 16 by photolithography, the first metal film 9 is formed by electroplating. After removing the film resist pattern 16, to newly form copper of the third metal film 8, a resist is formed with a diameter of Ø40 μm to the upper portion of the contact terminal.

In the example described in the third embodiment, a height of the contact terminal after completing the thin-film probe sheet is set to be 45 to 55 μm, and thus a film thickness of the copper of the third metal film 8 is 10 μm≦d3≦35 μm.

Subsequently, the process to fabricate the thin-film probe sheet including: formation of the insulating layer, formation of through-holes, formation of wiring and protective layer; removal of the silicon oxide film, silicon substrate, and the plating base metal film by etching; and further, etching of the second and third metal films is performed in the same process as the first embodiment, and thus a thin-film probe sheet achieving a height of contact terminal of 45 to 55 μm is provided.

### Fourth Embodiment

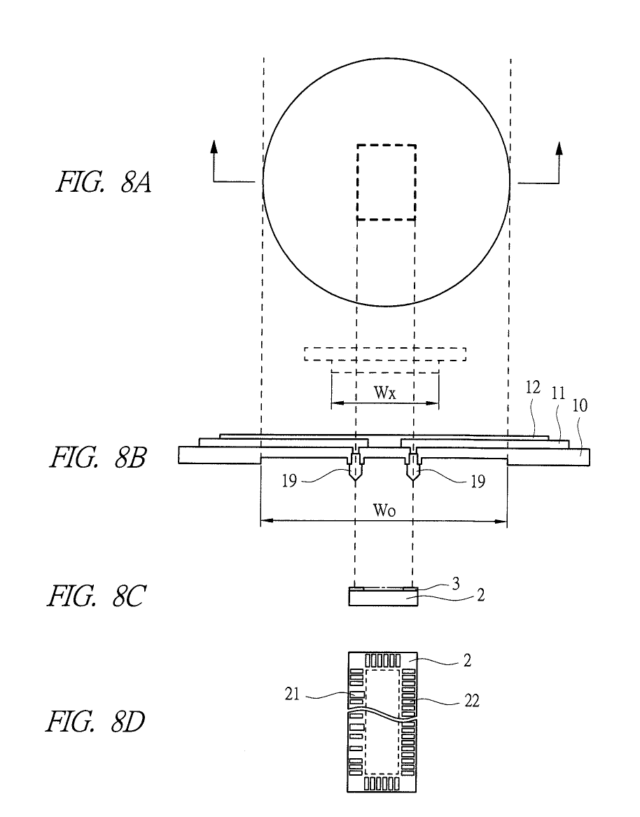

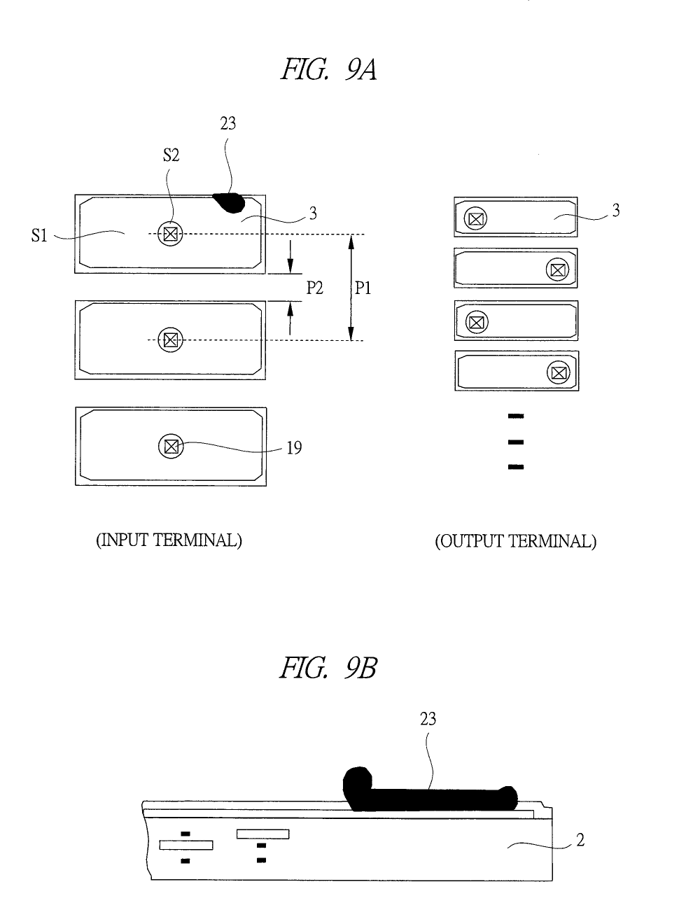

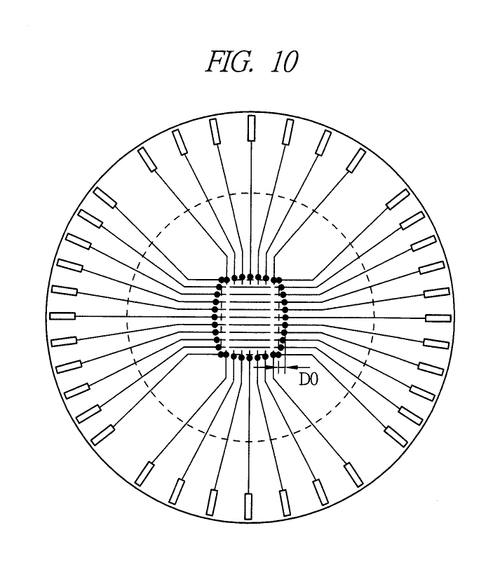

FIGS. 8A-8D are structure diagrams illustrating an arrangement of a thin-film probe sheet according to a fourth embodiment and an electrode pad of a semiconductor device compatible to a liquid display panel. FIGS. 9A and 9B are plan views illustrating an outline of an arrangement relation between electrode pads and contact terminals, and a schematic diagram of across section illustrating a plating segregation of the electrode pad of a semiconductor device to which gold bumps are formed.

In the fourth embodiment, the thin-film probe sheet and an example of an aspect of a semiconductor chip 2 that is an inspected object are illustrated in FIGS. 8A to 8D.

FIGS. 8A and 8B illustrate a plan view and a cross-sectional view of the whole of the sheet illustrated in FIG. 4. FIG. 8C illustrates a cross section illustrating a relation between the semiconductor chip 2 that is an inspected object and the electrode pad 3. FIG. 8D illustrates an example of a plan view of the semiconductor chip 2 that is an inspected object on which the electrode pad 3 is disposed.

Herein, a configuration of a thin-film probe sheet for inspecting a controlling semiconductor device (hereinafter, LCD: liquid crystal display) driver such as a liquid crystal display panel to which a reduction of pitch of the electrode pads has been significantly implemented will be described.

Regarding the electrode pitch of the LCD driver, along with a resolution improvement and a size enlargement of display panels, sub-50 μm miniaturization and an increase in wiring density per chip have been rapidly advanced.

The configuration of the electrode pad 3 of the LCD driver illustrated in FIG. 8D is an example of arranging input terminals to a side on the left, and output terminals to the other three sides in the figure. As to an arranging pitch of each electrode pad 3, since an arranging pitch and a pad area are large in an input-side electrode pad 21 which requires large current capacity for, for example, a power system and a ground system in addition to a signal system line on the input terminal side, contact terminals formed to the thin-film probe sheet can form an arrangement pattern in which the contact terminals are aligned in one line, and thus there are few problems.

Meanwhile, as to an arrangement of contact terminals of an output-side electrode pad 22 to be a subject of signal line drive on the output terminal side, as mentioned above, introducing a narrower pitch is becoming mandatory relative to an increase of signal lines and miniaturization to sub-50 μm.

An outline of an arrangement configuration of contact terminals of the thin-film probe sheet eyeing a narrower pitch such as LCD drivers is illustrated in FIGS. 9A and 9B. FIG. 9A illustrates outline diagrams illustrating an aspect of an arrangement of electrode pads, and FIG. 9B illustrates an example of a product type of an LCD driver in which gold bumps are formed on an electrode pad.

In the arrangement of contact terminals, as illustrated in FIG. 9A, the relation of the electrode pads 3 and contact terminals is S1>S2 wherein a terminal tip area S2 is sufficiently smaller than a pad area S1; and P1>P2 wherein an electrode pad space P2 is sufficiently smaller than a terminal pitch P1, so that terminals of the input-side electrode pad 21 can be aligned in one line and the contact terminals 19 of the output-side electrode pads 22 are formed to make contacts in a zigzag arrangement, thereby achieving a narrow-pitch terminal alignment.

In addition, in the case of a semiconductor device such as an LCD driver to which gold bumps are formed to electrode pads, if a thickness of the usually formed gold bump is very thick, an abnormal segregation protrusion of plating 23 may be sometimes generated due to influence of foreign matter such as abnormal segregation of the plating film or the like, and thus factors other than damage to the terminal due to externally taken-in foreign matter should be considered.

The abnormal segregation protrusion of plating 23 is prone to be generated in a periphery of the pad as illustrated in FIGS. 9A and 9B, and its size sometimes reaches several tens of μm.

In the fourth embodiment, a large space region in which the second metal film 7 and the third metal film 8, which are selectively removable to the contact terminal 19 are formed, is formed to the space region 18 in a periphery of the contact terminal 19 in the thin-film probe sheet, and thus the contact terminal has a larger height and a narrower pitch, and a longer lifetime can be achieved without generating critical damage to the fine contact terminals and the sheet surface in the periphery of the contact terminals.

### Fifth Embodiment

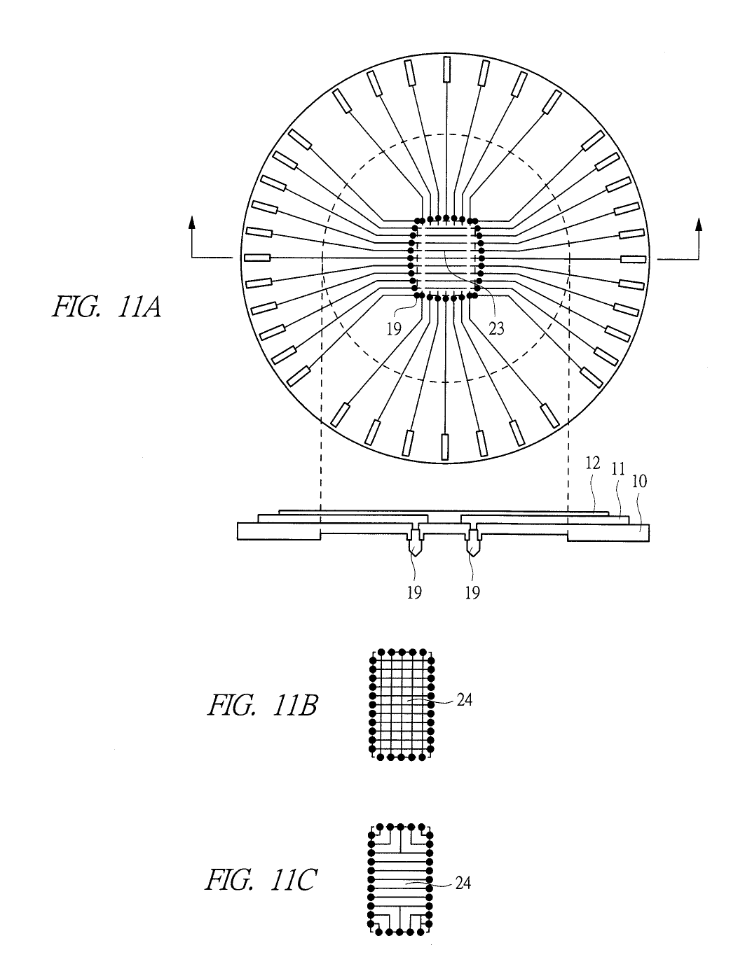

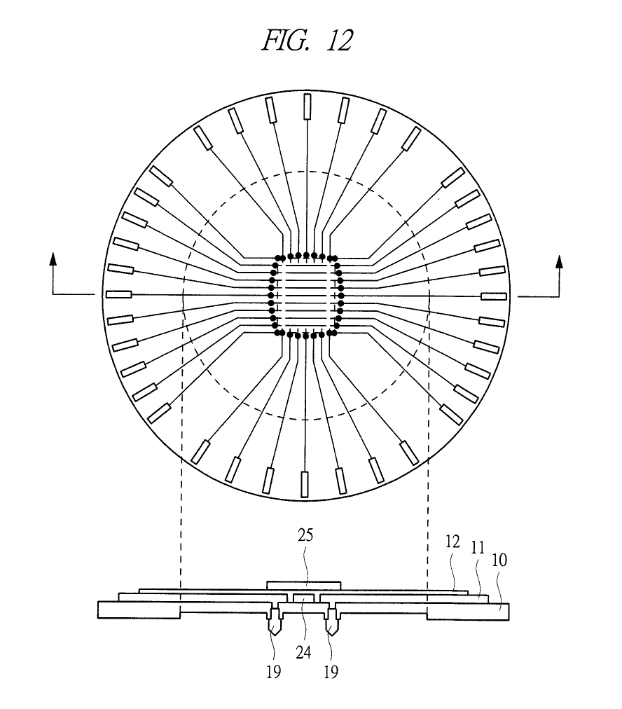

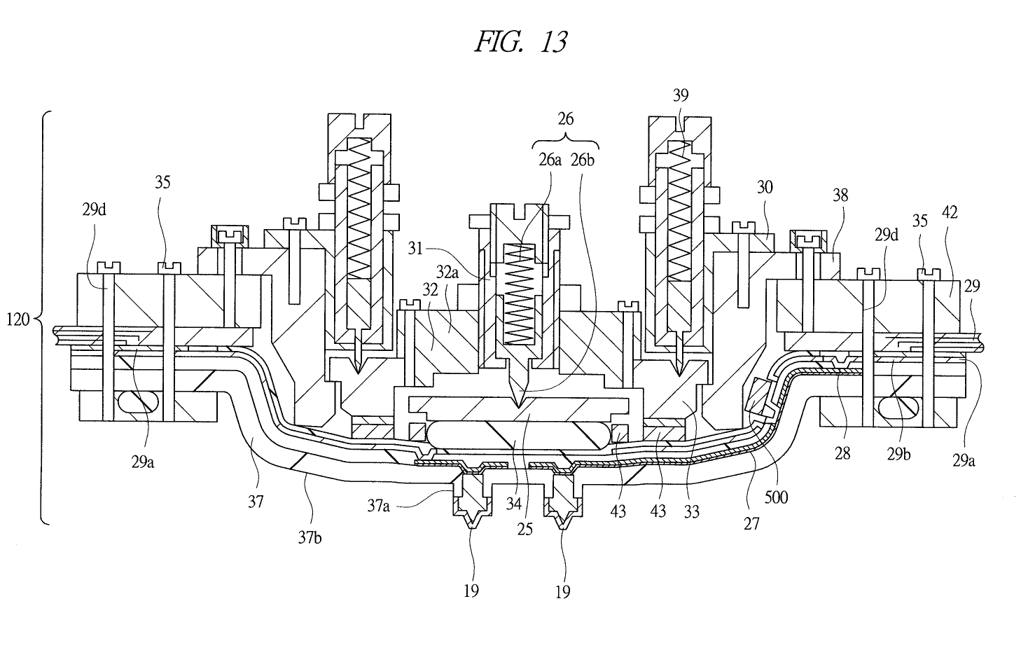

FIG. 10 is a schematic diagram of a planar appearance of a thin-film probe sheet according to a fifth embodiment for describing problems of the thin-film probe sheet. FIGS. 11A-11C are schematic diagrams of a planar appearance and a wiring configuration of the thin-film probe sheet of FIG. 10 in which a dummy wiring is formed in a vicinity of contact terminals. FIG. 12 is a schematic diagram illustrating a thin-film probe sheet of FIG. 10 on which a dummy wiring and a supporting metal are formed in a contact terminal region.

The fifth embodiment relates to a sheet configuration for improving a positional accuracy of contact terminals in the thin-film probe sheet having a configuration according to any of the first to fourth embodiments.

An outline of a planar appearance of the thin-film probe sheet fabricated in the configuration of any of the first to fourth embodiments, and an example of a problem of the thin-film probe sheet are illustrated in FIG. 10.

The thin-film probe sheet on which wirings are uniformly led from contact terminals to the periphery of the sheet is mounted to a probe card with a highly accurate positioning. As to the product type such as the LCD driver described in the fourth embodiment in which introduction of a narrower pitch is significant, it is important to maintain a positional accuracy (pitch, height) of the contact terminals at ±2 μm or smaller. The contact terminals are assembled with a high accuracy in accordance with the electrode pads of the subject semiconductor device with applying tension to the sheet with an adequate pressing amount by a pressing mechanism (pressing means) formed of a spring probe 26 and a push piece 25 illustrated in FIG. 13 etc. described later.

However, as illustrated in FIG. 10, when there is a pattern space of the polyimide film as it is forming the base sheet in the area in which the contact terminals are arranged, an uneven extension may occur in the sheet upon assembly adjustment, causing a positional shift of contact terminals as denoted by DO in FIG. 10.

In addition, in a pressuring operation upon an inspection, due to influence of the pattern space, it is impossible to uniformly apply load the same as that to the area in which the contact terminals are aligned and wirings are formed, and thus an accuracy lowering is posed in the height of the contact terminals.

Further, among characteristics inspections of various semiconductor devices by a semiconductor inspection apparatus, some of them inspect in a high-temperature regime of 100° C. or higher depending on the product type. Also in that case, the contact terminal alignment initially having a highly accurate positioning may be affected by a positional shift due to thermal behavior of the polyimide film.

Examples of a structure maintaining and improving the positional accuracy in the sheet plane during assembly operation are illustrated in FIGS. 11A to 11C and FIG. 12.

FIG. 11A illustrates a plane of the whole sheet illustrated in FIG. 4, and a cross section of an aspect in which a dummy wiring is formed in a pattern area in which terminals are aligned. FIGS. 11B and 11C illustrate an example of a structure of dummy wirings formed in the pattern area in which terminals are aligned.

FIG. 12 illustrates a configuration example in which a supporting metal for maintaining a positional accuracy including the area in which contact terminals are aligned is attached.

A dummy wiring 24 to be formed in the pattern area in which contact terminals are aligned is formed by plating at the same time with the step of arranging the wiring 11 for lead by the semi-active method in a conventional technology or the first embodiment described above, and any pattern as illustrated in FIGS. 11A to 11C is formed in accordance with terminal alignments of product types.

By forming the dummy wiring 24, a local positional shift in the assembly step of the thin-film probe card described above is improved, and thus the position of the pattern of the contact terminals in plane can be maintained with a high accuracy.

In addition, to improve the positional accuracy in the high-temperature region in the characteristics inspection, as illustrated in FIG. 12, the push piece 25 made of metal is directly attached so that the area in which the contact terminals are formed is included.

For the push piece 25 made of metal, an invar-based material or 42 alloy having almost the same thermal coefficient as a silicon base material of the semiconductor device to be inspected is preferable. The push piece 25 is flatly attached directly to the protective film 12 for wiring of polyimide in a final step of film thinning by an epoxy-based adhesive or silicone-based adhesive.

Herein, the push piece 25 made of 42 alloy having a plate thickness of 2 mm is adhered by an epoxy-based Aremco-Bond™ (product of Aremco Products, Inc.).

According to this structure, it is possible to fabricate a thin-film probe sheet in which contact terminals to be transferred from a photomask pattern corresponding to a product type are arranged on a silicon substrate at a high accuracy as they are. Further, it is possible to mount the thin-film probe sheet to a probe card with maintaining the accuracy, and also, it is possible to maintain positions in plane of the contact terminals at a high accuracy regardless of factors in characteristics inspection environment during operation of the semiconductor inspection apparatus.

Consequently, according to the structure of the thin-film probe sheet according to the fifth embodiment, a large area, in which the contact terminals and the second metal film and the third metal film selectively removable by etching are previously formed, is formed in the space region around the contact terminals 19. Thus, the contact terminals have a large height, and thus both a narrower pitch with an improved positional accuracy and a longer lifetime can be achieved at the same time without generating critical damages to the fine contact terminals and the sheet surface around the contact terminals.

### Sixth Embodiment

In a sixth embodiment, a thin-film probe sheet is fabricated in the same manner as the first to fifth embodiments described above except for the points that an aluminum film is not formed and the though-holes are formed by a laser such as a high-frequency YAG laser. According to the sixth embodiment, a mask for the aluminum film is not required, and thus the thin-film probe sheet same as the first to fifth embodiments described above can be fabricated at a low cost.

### Seventh Embodiment

FIG. 13 is a cross-sectional view illustrating an outline of an inspection probe card mounting a thin-film probe sheet according to a seventh embodiment.

As illustrated in FIG. 13, an inspection connection system 120 has an upper-portion fixing plate 30 and a push piece 25 fixed at a lower portion of the upper-portion fixing plate 30. The inspection connection system 120 has: a center pivot 31 which is a supporting axis; spring probes 26, which are pushing force applying means installed on the left and right and in front and back of the center pivot 31 and always applying constant pushing force with respect to vertical displacement; a presser member 32, to which pushing force of low load (about 3 to 50 mN per one pin) is applied from the spring probes 26, tiltably held at an inclination 32a to the center pivot 31; a thin-film probe sheet 37; an adhesive ring 43 fixedly attached to the thin-film probe sheet; an adhesive layer 34 provided between the thin-film probe sheet 37 and the push piece 25; and contact terminals 19 provided on the thin-film probe sheet 37.

A reason of using the configuration in which pushing force to the presser member 32 is applied by the spring probes 26 is for obtaining pushing force of low load substantially constant to displacement of the tip of the spring probe 26, and it is not always necessary to use the spring globe 26.

A presser member 42 is mounted to a wiring board 29. The wiring board 29 is formed of, for example, a resin material such as polyimide resin or glass epoxy resin, and has an electrode 29a, internal wiring 29b, and a connection terminal 29c.

The electrode 29a is formed of, for example, a via 29d connected to a part of the internal wiring 29b. The wiring board 29 and the thin-film probe sheet 37 are fixed by a screw 35 etc. by sandwiching the wiring board 29 and the thin-film probe sheet 37 by the presser members 42.

The thin-film probe sheet 37 is formed to have its periphery portion being extended to the outside of the adhesive ring 43, and the extended portion is smoothly bended outside the adhesive ring 43 and fixed onto the wiring board 29. At this time, a lead wiring 27 of an inspection wiring board is electrically connected to the electrode 29a provided to the wiring board 29.

As the adhesive layer 34, a material having elasticity is preferable, and an example of a polymer material having elastomeric properties is a silicone adhesive or the like.

Note that, since FIG. 13 is an outline diagram, the contact terminals 19 and the lead wiring 27 are illustrated for just few contact terminals, but a plurality of the contact terminals 19 and lead wirings 27 are arranged in the actual use.

As to the thin-film probe sheet of the present invention in which the height of the contact terminal is higher than conventional ones, in the wafer state, one or a plurality of semiconductor chips among a lot of arranged semiconductor chips is/are surely connected to the electrode pad 3 of aluminum or plating, etc., or the electrode pad 3 of gold bump etc., the electrode pad 3 having its surface formed with an oxide, by low load (about 3 to 50 mN per one pin) and at a stable low resistance value about 0.05 to 0.1Ω.

In this manner, it is not necessary to do an operation like scribing such as the cantilever method, and generation of indentation due to a scribe operation or rubbish of the electrode material can be prevented.

More specifically, in the thin-film probe sheet, the tips of the contact terminals 19 arranged in accordance with the alignment of the electrode pads are made sharp. Also, the area portion 37a, in which the contact terminals 19 are arranged, in the peripheral portion 37b is positioned under the presser means 32 with respect to the area portion 37b supported by the adhesive ring 43, and, while the push piece 25 is adhered to the thin-film probe sheet 37 by the adhesive layer 34 with a good flatness, the area portion 37a is jutted by the pressing mechanism, so that the sharp tip of the contact terminals 19 arranged in the thrown out area portion 37a can be vertically pressed to the electrode pads 3 of aluminum, plating etc., or the electrode pads 3 of gold bump etc. with low load. In this manner, an oxide formed on the surface of the electrode pad 3 can be easily penetrated to contact the metal conductor material of the electrode under the oxide, thereby ensuring a good contact at a stable low resistance value.

In addition, in the thin-film probe sheet according to the present invention, the region of forming the second metal film 7 and the third metal film 8 formed for increasing the height of terminal around the contact terminals 19 than conventional ones has a sufficiently large size than a diameter of the tip of the push piece 25 forming the pressing mechanism, thereby configuring the contact terminals 19 having a large height with a sufficiently large space area formed to the measuring plane. Further, an outer periphery surface of each contact terminal is covered with the polyimide film that is a sheet base material, thereby also significantly reducing damages due to externally taken-in foreign matter etc. mentioned above.

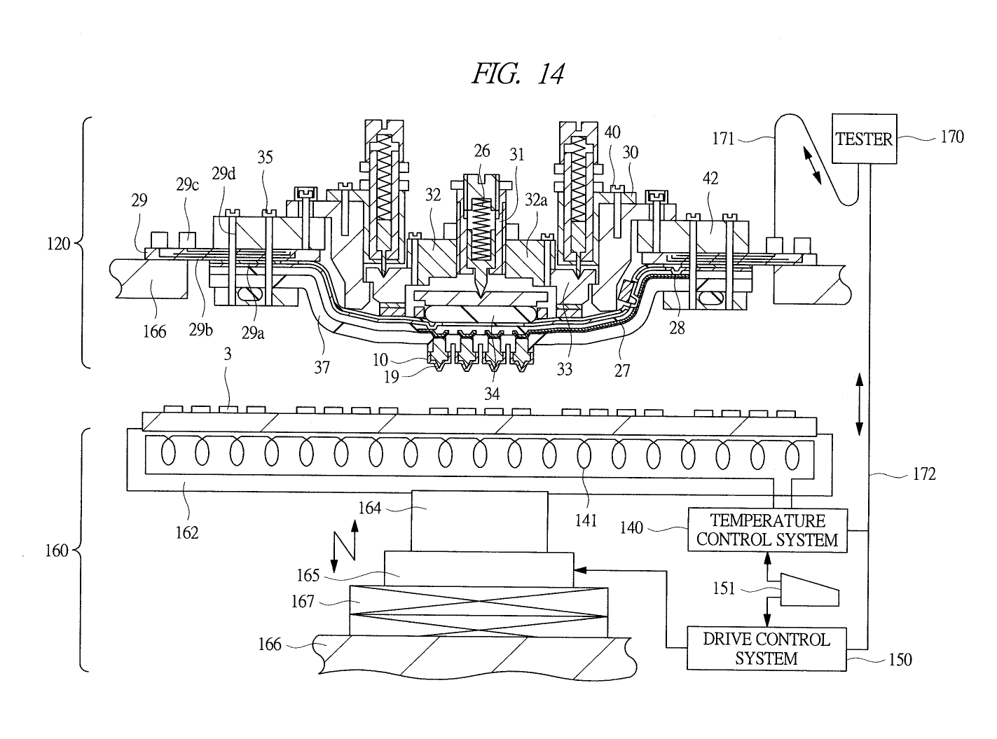

Next, an electric characteristics inspection to a semiconductor chip, which is an inspected object, using the probe card mounting the thin-film probe sheet according to the present invention will be described with reference to FIG. 14. FIG. 14 is a diagram illustrating a whole configuration of a semiconductor chip inspection apparatus for performing the electric characteristics inspection with applying desired load to a surface of a semiconductor wafer.

The semiconductor chip inspection apparatus includes: a sample supporting system 160 which supports a semiconductor (silicon) wafer 1; an inspection connection system 120 which is in contact with electrode pads 3 of the semiconductor wafer 1 and performs transmission and reception of electric signals; a drive control system 150 which controls operation of the sample supporting system 160; a temperature control system 140 which performs temperature control of the semiconductor wafer 1; and a tester 170 which performs inspections of electric characteristics of semiconductor chips 2.

A large number of semiconductor chips 2 are aligned on the semiconductor wafer 1, and a plurality of the microelectrode pads 3 for connecting with external equipments are aligned at a narrow pitch on a surface of each of the semiconductor chip 2. The sample supporting system 160 includes: a sample table 162 substantially horizontally provided for disposing the semiconductor wafer 1; a lifting axis 164 vertically provided to support the sample table 162; a lifting drive unit 165 which drives lifting of the lifting axis 164; and an X-Y stage 167 which supports the lifting drive unit 165.

The X-Y stage 167 is fixed onto a chassis 166. The lifting drive unit 165 includes, for example, a stepping motor etc. A rotational mechanism is provided to the sample table 162 so that the sample table 162 is rotatably displacable in a horizontal plane. Positioning operation of the sample table 162 is performed by combining operations of the X-Y stage 167, the lifting drive unit 165, and the rotational mechanism.

Above the sample table 162, the inspection connection system 120 is arranged. More specifically, the thin-film probe sheet 37 and the wiring board 29 illustrated in FIG. 14 are provided in a posture opposing the sample table 162 in parallel. Note that, in the sixth embodiment, the connecting terminal 29c of the wiring board 29 is formed of a coaxial connector. The connecting terminal 29c is connected to the tester 170 via a cable 171 connected to the connecting terminal 29c. The drive control system 150 is connected to the tester 170 via a cable 172. In addition, the drive control system 150 controls operation of the sample supporting system 160 by sending control signals to each drive unit of the sample supporting system 160.

More specifically, the drive control system 150 includes a computer inside, and controls operation of the sample supporting system 160 in accordance with progress information of test operation of the tester 170 transmitted via the cable 172. In addition, the drive control system 150 includes an operation unit 151, and receives inputs of various instructions about drive control, for example, inspections of manual operation.

The sample table 162 includes a heater (temperature adjustor) 141 for heating to perform a burn-in test on the semiconductor chip 2. The temperature control system 140 controls temperature of the semiconductor wafer 1 mounted on the sample table 162 by controlling the heater 141 of the sample table 162. Also, the temperature control system 140 includes the operation unit 151 and receives manual instructions about temperature control.

Hereinafter, operations of the semiconductor chip inspection apparatus will be described.

The semiconductor wafer 1 which is an inspected object is disposed on the sample table 162 with a positioning. An optical image of a plurality of fiducial marks separately formed on the semiconductor wafer 1 is taken by an imaging device such as an image sensor or a TV camera, and alignment information of the semiconductor chips 2 and alignment information the electrode pads 3 on the semiconductor chips 2 are recognized from positional information of the fiducial marks obtained by detecting positions of the plurality of fiducial marks from the obtained image signal in accordance with the type of the semiconductor wafer 1, and two-dimensional positional information for the whole of the electrode pad group is calculated.

In addition, an optical image of a specific contact terminal from the large number of contact terminals 19 formed on the sheet, or an optical image of the plurality of fiducial marks is taken by an imaging device such as an image sensor or a TV camera, and a position of a specific contact terminal or positions of the plurality of fiducial marks is/are detected. Based on the information, two-dimensional positional information as the whole of the contact terminal group is calculated.

The drive control system 150 calculates a shift amount of the two-dimensional positional information as the whole of the electrode pad group with respect to the two-dimensional positional information as the whole of the contact terminal group; controls drive of the X-Y stage 167 and the rotational mechanism based on the shift amount; and determines positioning of the group of electrode pads 3 formed on the plurality of semiconductor chips 2 aligned on the semiconductor wafer 1 at right under the group of the large number of arranged contact terminals 19.

Thereafter, based on a distance from the semiconductor wafer 1 to a surface of the area portion 37a in the thin-film probe sheet 37 measured by, for example, a gap sensor provided onto the sample table 162, the drive control system 150 operates the lifting drive unit 165 to lift up the sample table 162 until the whole surface of the large number of electrode pads 3 is pushed up by several from the point of contacting with the tips of the contact terminals.

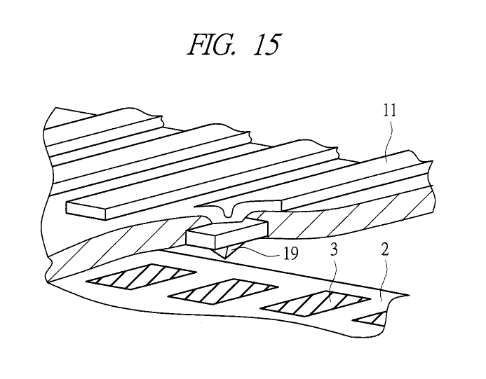

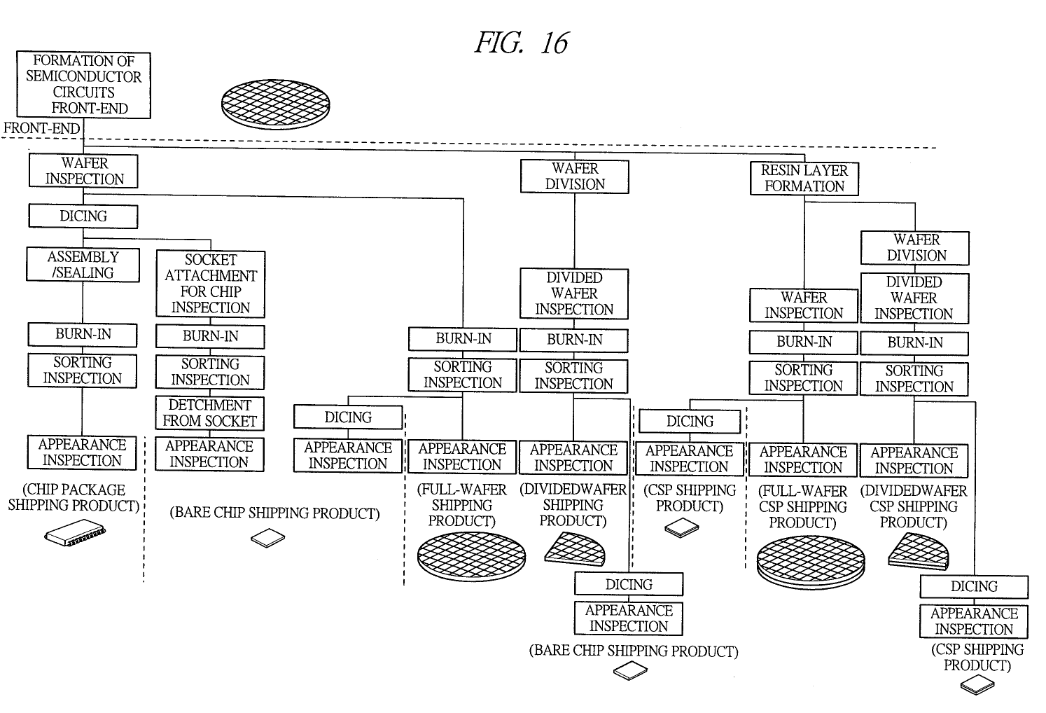

FIG. 15 illustrates an outline of an inspection on the semiconductor chip 2 to which the electrode pads 3 are arranged by the semiconductor chip inspection apparatus. In this manner, the whole of the number of contact terminals 19 are pushed out in parallel following the whole surface of the large number of electrode pads 3, and at the same time, with absorbing variations in the individual contact terminal heights, contacts by digging based on low load (about 3 to 50 mN per one pin) are made, so that each of the contact terminals 19 and each of the electrodes pad 3 are connected at a low resistance (0.01 to 0.1Ω).

When performing a burn-in test on the semiconductor chip 2 in this state, to control temperature of the semiconductor wafer 1 mounted on the sample table 162, the heater 141 of the sample table 162 is controlled by the temperature control system 140. Thus, the thin-film probe sheet 37 has flexibility, and it is preferably formed mainly of a resin having heat resistance. In the sixth embodiment, polyimide resin is used.

Transmission and reception of operation power and operation test signals are performed between the semiconductor chip 2 and the tester 170 formed to the semiconductor wafer 1 via the cable 171, wiring board 29, thin-film probe sheet 37, and contact terminals 19, and availability of electric characteristics of the semiconductor chip 2 is determined. The series of operations described above is performed on each of the plurality of the semiconductor chips 2 formed on the semiconductor wafer 1, and availability of electric characteristics is determined.

Finally, an inspection step using the semiconductor inspection apparatus or a method of manufacturing a semiconductor device including an inspection method will be described with reference to FIG. 16.

As illustrated in FIG. 16, in the method of manufacturing a semiconductor device according to the present invention, after a front-end process of fabricating circuits on the wafer and forming semiconductor chips, each process is performed in accordance with products such as chip package shipping product, bare chip shipping product, full wafer shipping product, divided wafer shipping product, bare chip shipping product, CSP shipping product, full-wafer CSP product, divided wafer CSP product, and CSP shipping product.

For example, for the chip package shipping product, after the front-end process, there are the steps of: inspecting electric characteristics of a plurality of semiconductor chips at wafer level by the semiconductor chip inspection apparatus according to the present invention; separating semiconductor chips into single pieces by dicing the wafer; and sealing the semiconductor device of the separated semiconductor chip by a resin or the like. Thereafter, through a burn-in, a sorting inspection, and an appearance inspection, good products after these inspections are shipped as chip packages.

Other products such as the bare chip shipping product, full-wafer shipping product, divided wafer shipping product, bare chip shipping product, CSP shipping product, full-wafer CSP shipping product, divided wafer shipping product, and CSP shipping product are as illustrated in FIG. 16.

The process of inspecting electric characteristics of the plurality of semiconductor chips at once by the semiconductor chip inspection apparatus according to the present invention is carried out at the timing of right after finishing the front-end process as described above; in a state of a divided wafer after dividing the wafer; in a state of a wafer after forming a resin layer on the wafer; or in a state of a divided wafer after forming a resin layer on the wafer and further dividing the wafer.

According to the step of inspecting electric characteristics of the semiconductor chip 2 according to the method of manufacturing a semiconductor device described above, by using the probe card disclosed in the present application, good contact characteristics can be obtained with a good positional accuracy.

More specifically, according to the inspection using the contact terminal 19 in a four-sided pyramid shape or a trapezoidal four-sided pyramid shape formed by plating using a hole as a mold formed in anisotropic etching of a substrate having crystalline property, it is possible to achieve stable contact properties with low contact pressure and to perform inspections without damaging the semiconductor chip positioned below. Also, since the structure is formed such that the plurality of contact terminals 19 are surrounded by the insulating film 10, excessive stress will not be applied to the contact terminals 19 even during inspection operation, thereby achieving sure and accurate contacts with electrodes of the semiconductor chip 2. It is also possible to inspect a plurality of the semiconductor chips 2 at once.

Further, since indentation to electrodes of the semiconductor chip 2 is small and like a dot (dot of a hole opened in a four-sided pyramid shape or a trapezoidal four-sided pyramid shape), a flat region without indentation is left on the electrode surface, and thus a plurality of times of inspections by the contacts can be performed as illustrated in FIG. 16.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention relates to a thin-film probe sheet, a thin-film probe card, and a connection apparatus used in an inspection of semiconductor chips, and alternately, a semiconductor chip inspection apparatus, a semiconductor chip manufacturing apparatus, or a semiconductor chip manufactured by using the semiconductor chip manufacturing apparatus. More specifically, the present invention is suitably applied to a connection to a semiconductor chip on which narrow-pitch microelectrode pads are aligned at a high density, or simultaneous connections to a large number of electrode pads.

What is claimed is:

1. A thin-film probe sheet comprising:
a plurality of contact terminals electrically connected to electrodes arranged to an inspected object;
individual wirings led out from the contact terminals through through-holes in an insulating layer; and
a plurality of peripheral electrodes connected to electrodes of a wiring board, wherein
a shape of the plurality of contact terminals is a four-sided pyramid or trapezoidal four-sided pyramid;
a second metal film and a third metal film which are selectively removable are provided in a peripheral region of a first metal film which forms the contact terminal;
a gap is formed between contact terminals by removing the second metal film and the third metal film in a back-end process; and
a height of the contact terminal is large.

2. A thin-film probe sheet comprising:
a plurality of contact terminals electrically connected to electrodes arranged to an inspected object;
individual wirings led out from the contact terminals through through-holes in an insulating layer; and
a plurality of peripheral electrodes connected to electrodes of a wiring board, wherein
a base material sheet forming the thin-film probe sheet has a region in which the plurality of contact terminals are formed, the region being positioned at a lower position than a surface of a peripheral region of the region.

3. A thin-film probe sheet comprising:
a plurality of contact terminals electrically connected to electrodes arranged to an inspected object;
individual wirings led out from the contact terminals through through-holes in an insulating layer; and
a plurality of peripheral electrodes connected to electrodes of a wiring board, wherein
a second metal film and a third metal film which are selectively removable are provided in a peripheral region of a first metal film which forms the plurality of contact terminals; and
the third metal film is formed like a step on the second metal film by shifting the third metal film to outside the contact terminal, so that a periphery of the contact terminals is covered with a resin base material which forms an insulating film.

4. The thin-film probe sheet according to claim 1, wherein
the contact terminal is formed of at least one metal selected from a group of nickel, rhodium, palladium, iridium, ruthenium, tungsten, chrome, copper, and tin, or alternatively, a stacked layer of alloy films of the metal.

5. The thin-film probe sheet according to claim 1, wherein
the second metal film and the third metal film are formed of at least one metal selected from nickel, copper, and tin.

6. A method of manufacturing a thin-film probe sheet including:
a plurality of contact terminals electrically connected to electrodes arranged to an inspected object; individual wirings led out from the contact terminals through through-holes in an insulating layer; and a plurality of peripheral electrodes connected to electrodes of a wiring board,
the method comprising the steps of :
forming a second metal film in peripheral regions of hole portions to which the plurality of contact terminals are formed, and then forming a first metal film forming the plurality of contact terminals;
forming a resist which covers the first metal film;
forming a third metal film on the second metal film, and then removing the resist;
forming the wiring connected to the first metal film, and then forming a protective layer which protects the wiring; and
removing the second metal film and the third metal film.

7. The method of manufacturing the thin-film probe sheet according to claim 6, wherein,
in the step of forming the second metal film and then forming the first metal film,
after the second metal film is formed in the peripheral regions of the hole portions to which the plurality of contact terminals are formed, a film resist is formed to an upper portion of the hole portions like a window roof by photolithography, and thereafter, the first metal film is formed to the hole portions.

8. The method of manufacturing the thin-film probe sheet according to claim 6, wherein,
in the step of forming the first metal film,
s contact terminal portion and a pillar portion formed of the first metal film are formed by one photolithography process and a plating process.

9. A probe card comprising the thin-film probe sheet according to claim 1, wherein a wiring board mounting the thin-film probe sheet, and a pressuring member which applies pressuring force are provided.

10. A semiconductor chip inspection apparatus comprising the thin-film probe sheet according to claim 1.
